(19) United States
(12) Patent Application Publication
(10) Pub. No.: US 2010/0301957 A1
(43) Pub. Date: Dec. 2, 2010

(54) RELAXATION OSCILLATOR USING SPINTRONIC DEVICE

(75) Inventors: Seung Young Park, Daejeon (KR); Younghun Jo, Seoul (KR)

Correspondence Address: MAIER & MAIER, PLLC, 1000 DUKE STREET, ALEXANDRIA, VA, 22314, US

(73) Assignee: Korea Basic Science Institute, Daejeon (KR)

(21) Appl. No.: 12/505,568

(22) Filed: Jul. 20, 2009

(30) Foreign Application Priority Data
May 28, 2009 (KR) 10-2009-0046953

(51) Int. Cl. H03K 3/02

(52) U.S. Cl. 331/143

(57) ABSTRACT

Disclosed herein is a relaxation oscillator using a spintronic device. The relaxation oscillator includes a power source unit, a spintronic device, and a capacitor. The power source unit applies power. The spintronic device is driven by the power applied by the power source unit, and has a variable voltage value depending on the intensity of a magnetic field. The capacitor is connected in parallel with the spintronic device, and is discharged when it assumes a minimum-voltage value in the threshold voltage range of the spintronic device and charged when it assumes a maximum voltage value in the threshold voltage range.

This patent application claims the benefit of priority under 35 U.S.C. § 119 from Korean Patent Application No. 10-2009-0046953 filed May 28, 2009, the contents of which are incorporated herein by reference.

### BACKGROUND OF THE INVENTION

1. Field of the Invention

The present invention relates to technology for implementing a relaxation oscillator using a spintronic device.

2. Description of the Related Art

A relaxation oscillator is implemented using a transistor-based device having two threshold voltages, such as a Schmitt trigger or a window comparator, so as to achieve oscillation.

A Schmitt trigger has two different threshold voltages V_{LT} and V_{HT} depending on the output states, as shown in FIGS. 1A and 1B. In these drawings, ρ₁ is a function of υ₀, +Vₛₐₜ is saturation voltage in the plus (+) direction, and −Vₛₐₜ is saturation voltage in the minus (−) direction.

Furthermore, a Schmitt trigger may be constructed of separate transistors TRs, as shown in FIGS. 2A and 2B. In this case, the condition R_{C1}>R_{C2} must be met and two threshold voltages V_{LT} and V_{HT} are used to drive it.

A circuit for generating periodic waveforms through the charging and discharging of a capacitor is referred to as a relaxation oscillator. A conventional relaxation oscillator is a square wave generator using a Schmitt trigger ST, as shown in FIG. 3. Here, assuming that the output υ₀ of the Schmitt trigger ST is −Vₛₐₜ, which is saturation voltage in the negative (−) direction, a capacitor C is exponentially charged to +Vₛₐₜ, which is saturation voltage in the positive (+) direction, at time constant RC. When υ_{c} reaches the threshold voltage V_{HT} of the Schmitt trigger ST, υ₀ is switched to −Vₛₐₜ and the capacitor C is exponentially discharged at time constant RC. Furthermore, when υ_{c} reaches the threshold voltage V_{LT} of the Schmitt trigger ST, υ₀ is switched to +Vₛₐₜ. As described hitherto, periodic square waves are generated in the output of the Schmitt trigger ST due to the repetition of the charging and discharging of the capacitor C.

The conventional relaxation oscillator has problems in that a large number of electronic devices, such as transistors, are used for the manufacture of it, so that the manufacturing cost thereof is high, the size thereof is large and high power consumption is incurred.

Furthermore, a conventional oscillator using a spintronic device uses the characteristic of oscillating in the GHz band when current 1.5 to 2 times higher than critical current at which magnetization reversal occurs is applied and a magnetic field also is applied. In this case, there are problems in that a spintronic device is easily broken down due to high applied current and output is low at the pW level regardless of the application of a high current.

Furthermore, there is a problem in that the oscillating characteristic is chiefly observed in a Giant Magnetoresistive (GMR) spintronic device but cannot be observed in a Magnetic Tunnel Junction (MTJ) spintronic device which has relatively poor durability.

Furthermore, the conventional oscillator using a spintronic device is difficult to put into practical use from the viewpoint of durability.

### SUMMARY OF THE INVENTION

Accordingly, the present invention has been made keeping in mind the above problems occurring in the prior art, and an object of the present invention is to provide a relaxation oscillator using a spintronic device, which does not use the transistors used in the conventional relaxation oscillator, so that the number of parts of the relaxation oscillator is reduced and the circuit of the relaxation oscillator is simplified, with the result that the manufacturing cost and power consumption of the relaxation oscillator are reduced and the volume of the relaxation oscillator is minimized.

Furthermore, another object of the present invention is to provide a relaxation oscillator using a spintronic device, which is capable of performing tuning in a wide frequency range ranging from a very few Hz to the GHz region.

Furthermore, still another object of the present invention is to provide a relaxation oscillator using a spintronic device, which is capable of achieving high output using magnetization reversal.

In order to accomplish the above object, the present invention provides a relaxation oscillator using a spintronic device, including a power source unit configured to apply power; a spintronic device configured to be driven by the power applied by the power source unit and to have a variable voltage value depending on the intensity of a magnetic field; and a capacitor connected in parallel with the spintronic device, and configured to be discharged when it assumes a minimum voltage value in the threshold voltage range of the spintronic device and to be charged when it assumes a maximum voltage value in the threshold voltage range.

Here, the power source unit may be a voltage source that applies voltage as the power.

The relaxation oscillator may further include a resistance element connected in series between the voltage source and the spintronic device and configured to vary the voltage applied by the voltage source to a drive voltage value suitable for driving of the spintronic device.

The relaxation oscillator may further include an electromagnet that varies the voltage value of the spintronic device by applying a magnetic field to the spintronic device.

The spintronic device may be a self-biased magnetic device that generates a magnetic field by itself.

The power source unit may be a current source that applies current as the power.

### BRIEF DESCRIPTION OF THE DRAWINGS

The above and other objects, features and advantages of the present invention will be more clearly understood from the following detailed description taken in conjunction with the accompanying drawings, in which:

FIGS. 1A and 1B are diagrams showing the basic circuit and operation of a Schmitt trigger, respectively;

FIGS. 2A and 2B are diagrams showing the circuit and operation of a Schmitt trigger constructed of individual transistors, respectively;

FIG. 3 is a circuit diagram of a conventional relaxation oscillator;

FIG. 4 is a circuit diagram of a relaxation oscillator using a spintronic device according to an embodiment of the present invention;

FIG. 5 is a diagram showing the dependency of resistance on bias voltage on the basis of the intensity of a magnetic field in the spintronic device of FIG. 4;

FIG. 6 is a phase diagram showing magnetization reversal on the basis of the intensity of the magnetic field of the spintronic device of FIG. 4;

FIG. 7 is a phase diagram showing the magnetization reversal of a self-biased spintronic device in which a structure capable of applying a magnetic field by itself has been added to the spintronic device of FIG. 4; and

FIG. 8 is a circuit diagram of a relaxation oscillator using a spintronic device according to another embodiment of the present invention.

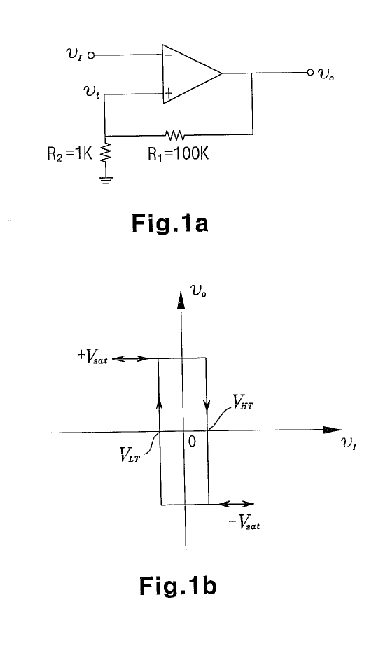

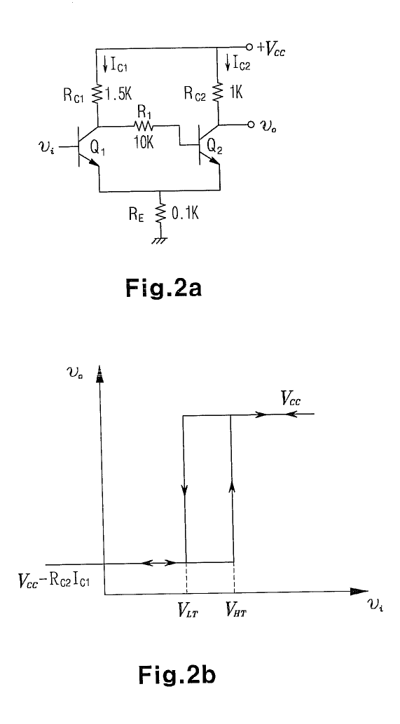

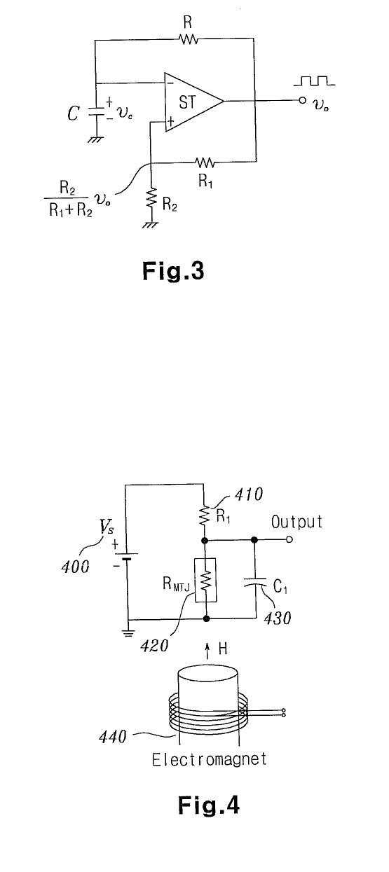

### DESCRIPTION OF THE PREFERRED EMBODIMENTS

Reference now should be made to the drawings, in which the same reference numerals are used throughout the different drawings to designate the same or similar components. In the following description of the present invention, detailed descriptions of related well-known functions or constructions will be omitted in order to prevent the gist of the present invention from being obscured.

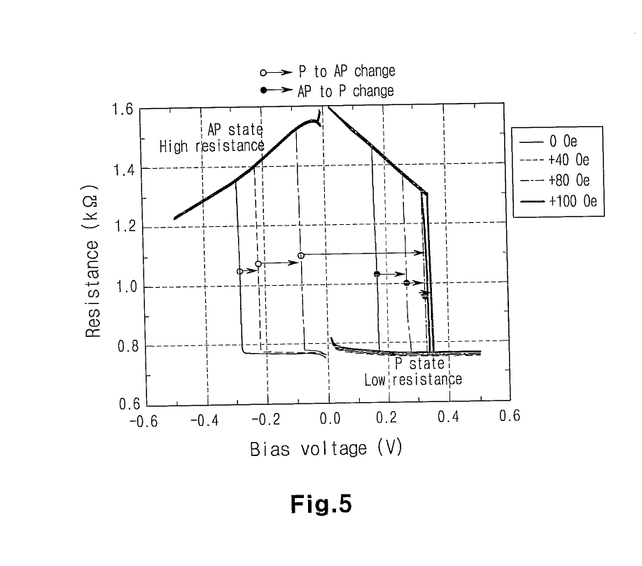

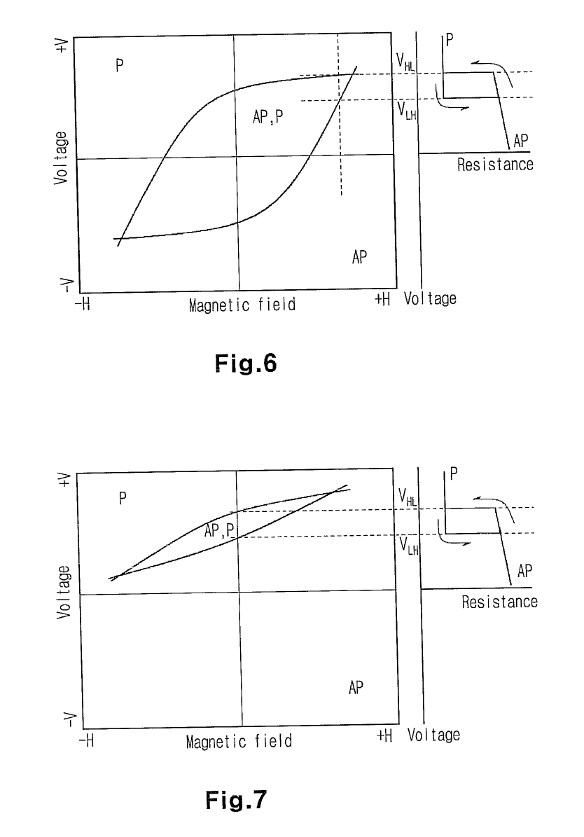

FIG. 4 is a circuit diagram of a relaxation oscillator using a spintronic device according to an embodiment of the present invention, FIG. 5 is a diagram showing the dependency of resistance on bias voltage on the basis of the intensity of a magnetic field in the spintronic device of FIG. 4, and FIG. 6 is a phase diagram showing magnetization reversal on the basis of the intensity of the magnetic field of the spintronic device of FIG. 4.

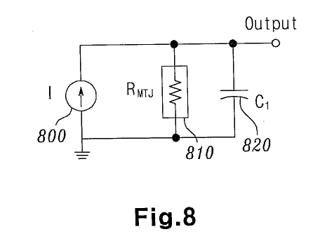

FIG. 7 is a phase diagram showing the magnetization reversal of a self-biased spintronic device in which a structure capable of applying a magnetic field by itself has been added to the spintronic device of FIG. 4, and FIG. 8 is a circuit diagram of a relaxation oscillator using a spintronic device according to another embodiment of the present invention.

The embodiments of the present invention will now be described in conjunction with the above drawings.

FIG. 4 shows a relaxation oscillator using a spintronic device according to an embodiment of the present invention. As shown in FIG. 4, the relaxation oscillator includes a power source unit 400, a spintronic device 420, and a capacitor 430.

The power source unit 400 is a voltage source which applies voltage as power for oscillation.

Furthermore, the spintronic device 420 is driven by the power which is applied by the power source unit 400, and has a voltage value which varies depending on the intensity of a magnetic field.

Here, the relaxation oscillator may further include a resistance element connected in series between the voltage source and the spintronic device 420 and configured to vary voltage, applied by the voltage source, to appropriate drive voltage at which the spintronic device can be driven, and an electromagnet 440 configured to vary the voltage value of the spintronic device by applying a magnetic field to the spintronic device 420.

Furthermore, the capacitor 430 is connected in parallel to the spintronic device 420, and is discharged when it has a minimum voltage value in the threshold voltage range of the spintronic device and charged when it has a maximum voltage value in the threshold voltage range.

That is, in the relaxation oscillator using a spintronic device according to the present embodiment of the present invention, the voltage source is provided as a power source, the electromagnet 440 capable of controlling the intensity of a magnetic field is disposed near the spintronic device 420, the resistance element 410 capable of controlling voltage applied to the spintronic device 420 is connected in series, and the capacitor 430 capable of controlling an oscillation period (frequency) using the times required for charging and discharging is connected in parallel, as shown in FIG. 4.

The magnetic field and voltage applied to the spintronic device 420 generate two threshold voltages which increase and decrease the electrical resistance of the spintronic device, respectively. When the power source is a DC voltage source and voltage is determined, an appropriate operating voltage range can be achieved by varying the resistance element 410 connected in series to the spintronic device. In this case, operation is started by applying the power and controlling the resistance element 410 so that a voltage slightly higher than the threshold voltage V_{HL} (at which the transition from a high resistance state to a low resistance state occurs) is applied to the spintronic device 420.

FIG. 5 is a diagram showing the dependency of resistance on bias voltage on the basis of the intensity of the magnetic field 0 Oe, 40 Oe, 80 Oe and 100 Oe in the spintronic device 420 of FIG. 4. The voltage which causes the resistance state to vary from a high resistance state to a low resistance state or causes the resistance state to vary oppositely is varied in any one direction depending on the magnetic field. In the present specification, the variation in the resistance state is referred to as “magnetization reversal.” Furthermore, FIG. 6 is a phase diagram showing magnetization reversal on the basis of the intensity of the magnetic field of the spintronic device 420 of FIGS. 4 and 5. When the intensity of the current I or voltage I×R_{MTJ} which passes through the spintronic device 420 reaches the threshold current (I_{HL}: for the transition from a high resistance state H to a low resistance state L; I_{LH}: for the transition from a low resistance state L to a high resistance state H) or threshold voltage (V_{HL}=I_{HL}×R_{MTJ}, V_{LH}=I_{LH}×R_{MTJ}, and R_{MTJ} is the resistance of the spintronic device of FIG. 4) which is sufficient to attain magnetization reversal, the phenomenon in which the magnetization directions of a free layer and a pinned layer are consistent with each other or are opposite to each other occurs. There is a tendency for the threshold voltages to increase or decrease depending on the intensity of the magnetic field applied to the spintronic device, as shown in FIG. 5. Furthermore, the difference between the two threshold voltages that increase or decrease the electrical resistance of the spintronic device also varies. In particular, the higher the intensity of the magnetic field applied to the spintronic device 420 is, the greater two threshold voltages gradually become and the narrower the interval between the two threshold voltages gradually becomes.

That is, when the spintronic device 420 enters a low resistance state, a low voltage

$${V}_{S} \frac{{R}_{M T J ( low )}}{{R}_{1} + {R}_{M T J ( law )}}$$

is applied to the spintronic device 420 according to voltage and the capacitor 430 starts to be discharged. Here, the voltage V_{c}(t) of the capacitor 430 over time is represented by the following Equation 1:

V_{c}(t)=V_{F}−(V_{F}−V_{I})e^{-t/τ},(t>0) (1)

In Equation 1, V_{F} is a final voltage to which the capacitor 430 can be charged, V_{I} is an initial voltage from which the capacitor 430 starts to be charged, t is time, and τ is a time constant obtained by multiplying the parallel combined resistance of the resistance R_{MTJ} of the spintronic device and resistance R_{I} by the value the capacitor 430. The time required for discharging is derived from Equation 1 as

$$τ ln ( 1 + \frac{2 {R}_{1}}{{R}_{M T J}} ) .$$

In this case, R_{MTJ} is in a low resistance state.

When the discharge voltage of the capacitor 430 reaches the threshold voltage V_{LH} at which the transition of the spintronic device 420 from a low resistance state to a high resistance state occurs, a high voltage

$${V}_{S} \frac{{R}_{M T J ( low )}}{{R}_{1} + {R}_{M T J ( law )}}$$

is applied to the spintronic device according to the voltage divider rule and the capacitor 430 starts to be charged. The time required for charging is

$$τ ln ( 1 + \frac{2 {R}_{1}}{{R}_{M T J}} ) .$$

as described above, where R_{MTJ} in a high resistance state.

The oscillation period T of the present oscillator is discharging time+charging time, and may be expressed by the following Equation 2:

$$T = 2 τ ln ( 1 + \frac{2 {R}_{1}}{1 / 2 ( {R}_{M T J ( low )} + {R}_{M T J ( high )} )} ) \qquad ( 2 )$$

The spintronic device 420 may be a self-biased magnetic device that generates a magnetic field by itself, and FIG. 7 is a phase diagram showing the magnetization reversal of a self-biased spintronic device in which a structure capable of applying a magnetic field by itself without requiring an externally applied magnetic field is added to the spintronic device of FIG. 4. In the case where there is no applied magnetic field, that is, in the case where an external magnetic field is 0 Oe, two threshold voltages are shown, as shown in FIG. 6.

The operation of an oscillator that adopts the spintronic device 420 exhibiting the characteristics of FIG. 7 and that is shown in FIG. 8 will now be described below.

The power of the current source applied to the spintronic device 420 produces two threshold voltages that increase and decrease the electrical resistance of the spintronic device 420, respectively.

The voltage I×R_{MTJ} applied across the spintronic device 420 can be set in an appropriate voltage range in which the oscillator can operate by adjusting the DC current source which is the power source. The operation is started by performing adjustment so that a voltage slightly higher than a threshold voltage V_{HL} at which the transition from a high resistance state to a low resistance state occurs is applied to the spintronic device 420.

When the spintronic device 420 enters a low resistance state, a low voltage IR_{MTJ(low)} is applied to the spintronic device 420 and the capacitor 430 starts to be discharged. In this case, the voltage V_{c}(t) of the capacitor 430 over time is expressed by the aforementioned Equation 1. In this Equation, τ is a time constant that is obtained by multiplying the resistance of the spintronic device with the value of the capacitor 430. The time required for discharging is obtained from Equation 1 as

$${R}_{M T J} C ln ( \frac{1 + {R}_{M T J}}{1 - {R}_{M T J}} ) .$$

In this case, R_{MTJ} is in a low resistance state.

When the discharge voltage of the capacitor 430 reaches the threshold voltage V_{LH} at which the spintronic device makes the transition from a resistance low state to a high resistance state, the high voltage IR_{MTJ(high)} is applied to the spintronic device 420 and the capacitor 430 starts to be charged. The time required for charging is very small, unlike that in the above-described case. The reason for this is that discharging is performed through R_{MTJ}, but charging is performed without using R_{MTJ} in such a way that charges are supplied directly from the current source.

Accordingly, the oscillation period T of the present oscillator is discharging time+charging time, and may be expressed by the following Equation 3:

$$T = τ ln ( \frac{1 + {R}_{M T J}}{1 - {R}_{M T J}} ) \qquad ( 3 )$$

Here, the power source unit may be a current source 800 that supplies current as power, as shown in FIG. 8. FIG. 8 is a circuit diagram of a spintronic device-type relaxation oscillator which adopts the current source 800 as a power source and is equipped with the device of FIG. 6 as a spintronic device. When current is applied and the thresh voltage V_{HL} is reached, the resistance and voltage of the spintronic device 810 are lowered, so that the capacitor 820 is discharged. When the capacitor 820 is discharged and then reaches a voltage V, the resistance and voltage of the spintronic device 810 are lowered, so that the capacitor 820 is charged.

The above-described relaxation oscillator using a spintronic device according to the present invention has advantages in that the number of parts of the relaxation oscillator is small and the circuit of the relaxation oscillator is simplified, compared with the conventional relaxation oscillator using transistors.

Furthermore, the relaxation oscillator has an advantage of being capable of performing tuning in a wide frequency band ranging from a very few Hz to the GHz region using the fast magnetization reversal of a spintronic device, compared with the conventional spin torque oscillator that outputs only frequencies in the GHz band through the variation of the capacity of a capacitor and an applied magnetic field, thus having a wide range of applicability.

Furthermore, the relaxation oscillator has an advantage of achieving high output using magnetization reversal, rather than using spin precession.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A relaxation oscillator using a spintronic device, comprising:
a power source unit configured to apply power;
a spintronic device configured to be driven by the power applied by the power source unit and to have a variable voltage value depending on intensity of a magnetic field; and
a capacitor connected in parallel with the spintronic device, and configured to be discharged when it assumes a minimum voltage value in a threshold voltage range of the spintronic device and to be charged when it assumes a maximum voltage value in the threshold voltage range.

2. The relaxation oscillator as set forth in claim 1, wherein the power source unit is a voltage source that applies voltage as the power.

3. The relaxation oscillator as set forth in claim 2, further comprising a resistance element connected in series between the voltage source and the spintronic device and configured to vary the voltage applied by the voltage source to a drive voltage value suitable for driving of the spintronic device.

4. The relaxation oscillator as set forth in claim 1, further comprising an electromagnet that varies the voltage value of the spintronic device by applying a magnetic field to the spintronic device.

5. The relaxation oscillator as set forth in claim 1, wherein the spintronic device is a self-biased magnetic device that generates a magnetic field by itself.

6. The relaxation oscillator as set forth in claim 1, wherein the power source unit is a current source that applies current as the power.
